(19) United States
(12) Patent Application Publication
(10) Pub. No.: US 2015/0108519 A1
(43) Pub. Date: Apr. 23, 2015

(54) LIGHT-EMITTING STRUCTURE

(71) Applicant: LEXTAR ELECTRONICS CORPORATION, HSINCHU (TW)

(72) Inventors: Ming-Chang TANG, Taichung City (TW); Chia-Hsian CHOU, Taoyuan County (TW); Nai-Wei HSU, Tainan City (TW)

(73) Assignee: LEXTAR ELECTRONICS CORPORATION, HSINCHU (TW)

(21) Appl. No.: 14/273,493

(22) Filed: May 8, 2014

(30) Foreign Application Priority Data
Oct. 18, 2013 (TW) 102137630

(51) Int. Cl. H01L 33/20

(52) U.S. Cl. CPC H01L 33/20
USPC 257/98

(57) ABSTRACT

A light-emitting structure is provided, including a substrate, an LED stacked structure formed on the substrate, and a plurality of cavities formed on the substrate surrounding the LED stacked structure. The LED stacked structure comprises an N-type epitaxial layer, an illumination layer, and a P-type epitaxial layer. A portion of the N-type epitaxial layer is exposed.

### CROSS REFERENCE TO RELATED APPLICATIONS

The present application is based on, and claims priority from, Taiwan Patent Application No. 102137630, filed on Oct. 18, 2013, the disclosure of which is hereby incorporated by reference herein in its entirety.

### BACKGROUND OF THE INVENTION

1. Field of the Invention

The application relates in general to a light-emitting structure, and in particular to a light-emitting structure with cavities.

2. Description of the Related Art

As shown in FIG. 1, a conventional light-emitting diode (LED) includes a substrate B, a p-type semiconductor P, an n-type semiconductor N, and an illumination layer E. When a voltage signal is applied to the p-type semiconductor P and the n-type semiconductor N, light is emitted from the illumination layer E. However, as shown in FIG. 1, total internal reflection may occur, such that light can not bounce out of the light-emitting diode, and the illumination efficiency of the light emitting diode can be reduced.

### BRIEF SUMMARY OF INVENTION

To address the deficiency of conventional LEDs, an embodiment of the invention provides a light-emitting structure, comprising a substrate, an LED stacked structure formed on the substrate, and a plurality of cavities formed on the substrate surrounding the LED stacked structure. The LED stacked structure comprises an N-type epitaxial layer, an illumination layer, and a P-type epitaxial layer. A portion of the N-type epitaxial layer is exposed.

### BRIEF DESCRIPTION OF DRAWINGS

The invention can be more fully understood by reading the subsequent detailed description and examples with references made to the accompanying drawings, wherein:

FIG. 1 shows a conventional light-emitting diode;

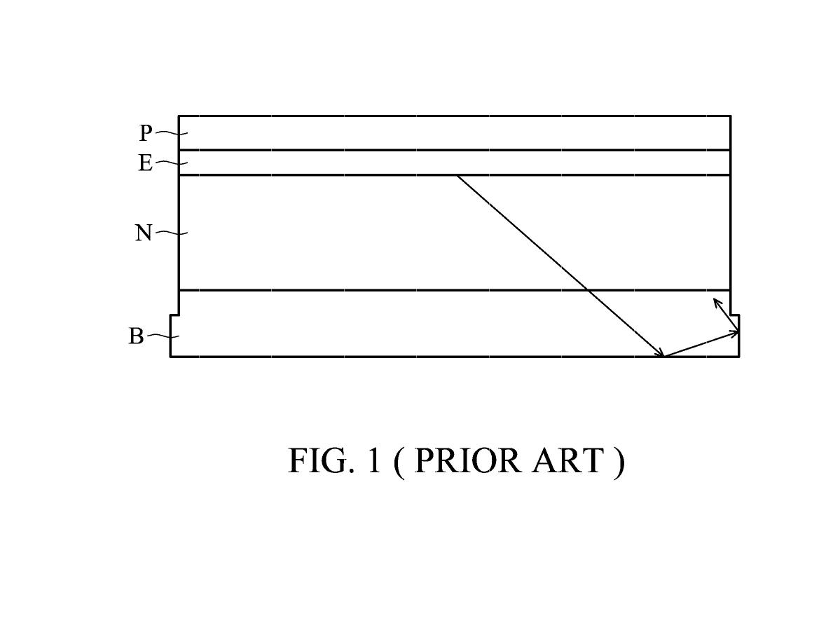

FIG. 2A is a perspective diagram of a light-emitting structure according to an embodiment of the invention;

FIG. 2B is a cross-sectional view taken along the line x-x of FIG. 2A according to an embodiment of the invention;

FIG. 3 is a perspective diagram of a light-emitting structure according to another embodiment of the invention; and

FIG. 4 is a perspective diagram of a light-emitting structure according to another embodiment of the invention.

### DETAILED DESCRIPTION OF INVENTION

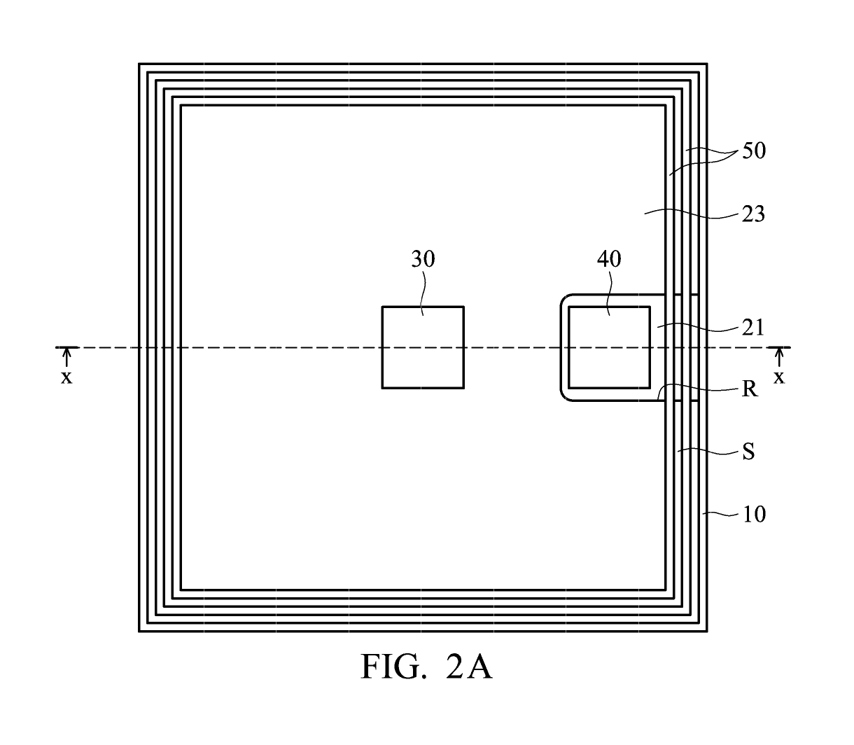

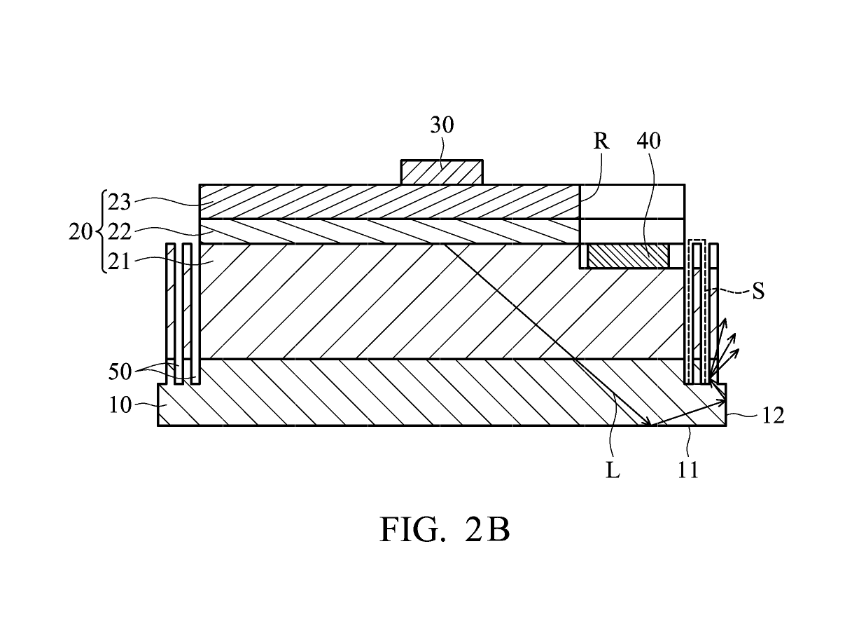

A light-emitting structure according to an embodiment of the invention is shown in FIGS. 2A and 2B, wherein FIG. 2B is a cross-sectional view taken along the line x-x of FIG. 2A. As shown in FIG. 2B, the light-emitting device comprises a substrate 10 and a platform-shaped LED stacked structure 20. The LED stacked structure 20 is formed on the substrate 10 including an N-type epitaxial layer 21, an illumination layer 22, and a P-type epitaxial layer 23. The N-type epitaxial layer 21 is disposed between the P-type epitaxial layer 23 and the substrate 10. The illumination layer 22 is disposed between the N-type epitaxial layer 21 and the P-type epitaxial layer 23. That is, the layers of the light-emitting device from bottom to top are the substrate 10, the N-type epitaxial layer 21, the illumination layer 22, and the P-type epitaxial layer 23.

Referring to FIGS. 2A and 2B, the projection area of the illumination layer 22 and the P-type epitaxial layer 23 on the substrate 10 is less than the projection area of the N-type epitaxial layer 21 on the substrate 10. Here, a portion of the N-type epitaxial layer 21 is uncovered by the illumination layer 22 and surrounds the illumination layer 22 and the P-type epitaxial layer 23. Furthermore, a U-shaped recess R is formed on the LED stacked structure 20 and adjacent to the sidewalls of the illumination layer 22 and the P-type epitaxial layer 23. Therefore, the portion of the N-type epitaxial layer 21 can be exposed to the top surface of the light-emitting structure through the recess R (as shown in FIG. 2A).

The light-emitting structure further comprises a first electrode 30, a second electrode 40, and a plurality of cavities 50. The cavities 50 are formed on the substrate 10 surrounding the LED stacked structure and extended through the N-type epitaxial layer 21. Specifically, a spacer S is formed between two adjacent cavities 50. In this embodiment, the spacer S includes a part of the substrate 10 and a part of the N-type epitaxial layer 21. As shown in FIG. 2B, the first electrode 30 connects to the top surface of the P-type epitaxial layer 23, and the second electrode 40 connects to the top surface of the N-type epitaxial layer 21 and is accommodated in the recess R.

As shown in FIG. 2B, when the first and second electrodes 30 and 40 are charged and the illumination layer 22 emits a light L, the light L is reflected by the bottom surface 11 and the side surface 12 of the substrate 10 to the cavities 50. It is noted that the cavities 50 can be formed by laser dicing and include a non-smooth surface. Therefore, when the light L impacts the cavities 50, it scatters to the external region of the light-emitting structure (as shown in FIG. 2B). Thus, more light can bounce out through the lateral sides of the light-emitting structure.

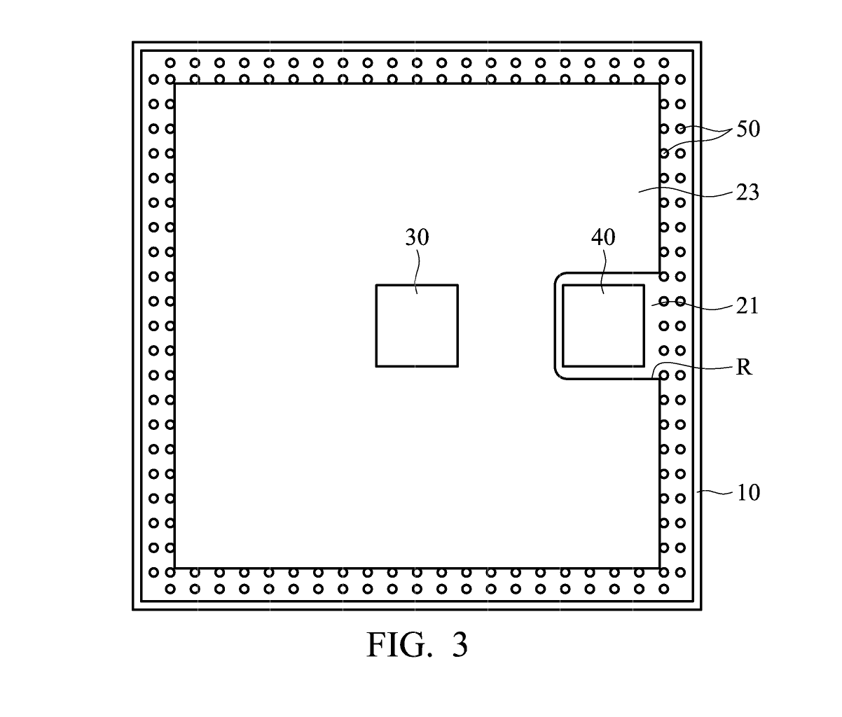

It is noted that the substrate 10 can be a sapphire substrate, the illumination layer 22 can be a multiple quantum well, and the width and the depth of the cavity 50 can be respectively 1 μm-30 μm and 1 μm-500 μm in this embodiment. As the cavities 50 surround the illumination layer 22 and the P-type epitaxial layer 23, the orthogonal projection of each of the cavities 50 on the substrate 10 has an annular structure. In another embodiment, four longitudinal cavities 50 can respectively be formed on four sides of the substrate 10. The orthogonal projection of each of the cavities 50 on the substrate 10 has a linear structure. Referring to FIG. 3, in another embodiment, the cavities 50 are a plurality of holes formed on the substrate 10. Thus, the orthogonal projection of each of the cavities 50 on the substrate 10 has a spot shape.

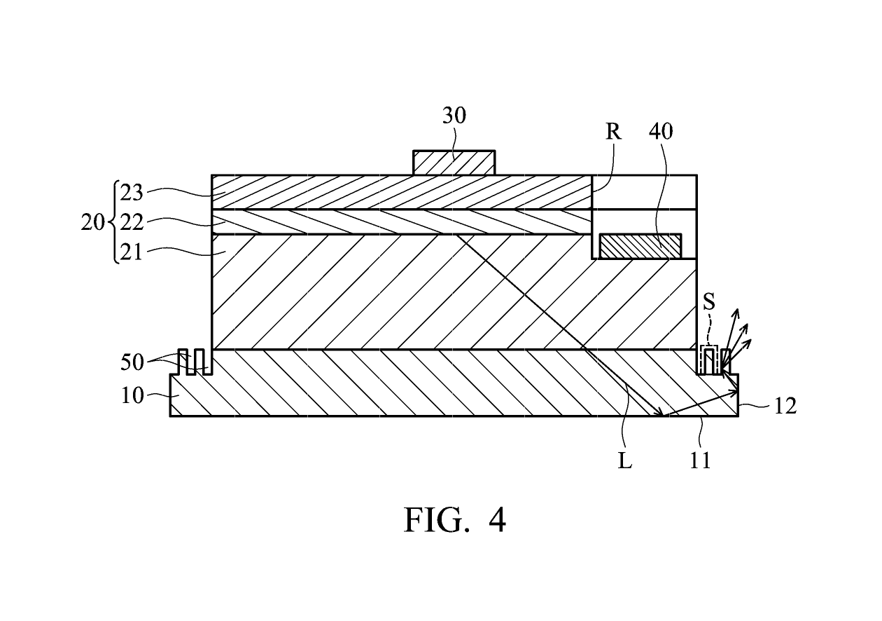

Referring to FIG. 4, in another embodiment of the invention, the part of the N-type epitaxial layer 21 which constitutes the part of a spacer S can be removed by wet etching. Thus, the light-emitting structure can be more robust, and damage to the spacer S due to collision can be prevented.

In summary, a light-emitting structure with cavities is provided. The cavities can prevent light restricted in the light-emitting structure owing to the total internal reflection, such that light can bounce out from the lateral sides of the light-emitting structure. Thus, the light bouncing out of the light-emitting structure can be facilitated, and the illumination efficiency of the light-emitting structure can be also improved.

While the invention has been described by way of example and in terms of preferred embodiment, it is to be understood that the invention is not limited thereto. On the contrary, it is intended to cover various modifications and similar arrangements (as would be apparent to those skilled in the art). Therefore, the scope of the appended claims should be accorded the broadest interpretation to encompass all such modifications and similar arrangements.

What is claimed is:

1. A light-emitting structure, comprising:
a substrate;
a platform-shaped LED stacked structure, formed on the substrate, including an N-type epitaxial layer, an illumination layer, and a P-type epitaxial layer, wherein a portion of the N-type epitaxial layer is exposed; and
a plurality of cavities, formed on the substrate surrounding the LED stacked structure.

2. The light-emitting structure as claimed in claim 1, wherein an orthogonal projection of each of the cavities on the substrate has a linear structure.

3. The light-emitting structure as claimed in claim 1, wherein an orthogonal projection of each of the cavities on the substrate has a spot shape.

4. The light-emitting structure as claimed in claim 1, wherein an orthogonal projection of each of the cavities on the substrate has an annular structure.

5. The light-emitting structure as claimed in claim 1, wherein the cavities are formed by laser dicing.

6. The light-emitting structure as claimed in claim 1, wherein a width of the cavity is 1 μm-30 μm, and a depth of the cavity is 1 μm-500 μm.

7. The light-emitting structure as claimed in claim 1, wherein the light-emitting structure further comprises a first electrode and a second electrode, the first electrode connects to a top surface of the P-type epitaxial layer, and the second electrode connects to an uncovered top surface of the N-type epitaxial layer, wherein the uncovered top surface is uncovered by the illumination layer.

8. The light-emitting structure as claimed in claim 1, wherein the light-emitting structure further comprises at least a spacer formed between two adjacent cavities, wherein the spacer includes a part of the substrate.

9. The light-emitting structure as claimed in claim 8, wherein the spacer includes a part of the N-type epitaxial layer.

10. The light-emitting structure as claimed in claim 1, wherein the substrate is a sapphire substrate.
